(19) United States
(12) Patent Application Publication
(10) Pub. No.: US 2025/0221311 A1
(43) Pub. Date: Jul. 3, 2025

(54) THERMOELECTRIC CONVERSION ELEMENT, JOINING MATERIAL, THERMOELECTRIC CONVERSION MODULE, THERMOELECTRIC CONVERSION SYSTEM, METHOD FOR GENERATING ELECTRIC POWER, AND METHOD FOR PRODUCING THERMOELECTRIC CONVERSION ELEMENT

(71) Applicant: Panasonic Intellectual Property Management Co., Ltd., Osaka (JP)

(72) Inventor: TSUTOMU KANNO, Kyoto (JP)

(21) Appl. No.: 19/051,288

(22) Filed: Feb. 12, 2025

Related U.S. Application Data
(63) Continuation of application No. PCT/JP2023/028074, filed on Aug. 1, 2023.

(30) Foreign Application Priority Data
Aug. 29, 2022 (JP) 2022-136162

(51) Int. Cl. H10N 10/817; H10N 10/01; H10N 10/17; H10N 10/853

(52) U.S. Cl. CPC H10N 10/817; H10N 10/01; H10N 10/17; H10N 10/853

(57) ABSTRACT

The present disclosure provides a thermoelectric conversion element that is advantageous from the viewpoint of inhibiting an increase in electric resistance in high-temperature air. A thermoelectric conversion element according to the present disclosure includes a first metal layer and a thermoelectric convertor. The thermoelectric convertor contains Mg and at least one selected from the group consisting of Sb and Bi. The thermoelectric convertor includes a thermoelectric conversion layer and a first joining layer. The first joining layer contains at least one selected from the group consisting of Fe and Ni. The first joining layer satisfies a condition of 2.5≤α/β≤6.5. In the condition, α is the content of Mg in terms of number of atoms in the first joining layer, and β is the sum of the contents of Sb and Bi in terms of number of atoms in the first joining layer.

### BACKGROUND

### 1. Technical Field

The present disclosure relates to a thermoelectric conversion element, a joining material, a thermoelectric conversion module, a thermoelectric conversion system, a method for generating electric power, and a method for producing a thermoelectric conversion element.

### 2. Description of the Related Art

Conventionally, thermoelectric conversion materials containing Mg and at least one selected from the group consisting of Sb and Bi have been known.

For example, Japanese Patent No. 6127281 describes a thermoelectric conversion material represented by Mg₃₊ₘAₐB_{b}D₂₋ₑEₑ. In this thermoelectric conversion material, D is at least one selected from the group consisting of Sb and Bi.

Tamaki et al., Advanced Materials 28, 10182-10187 (2016) describes thermoelectric conversion performance of certain n-type Mg_{3+δ}(Sb,Bi). For example, it states that a polycrystalline sintered body having a composition of Mg_{3.2}Sb_{1.5}Bi_{0.49}Te_{0.01} exhibits a ZT of 1.51±0.06 at 716 K.

Zhu et al., Journal of Power Sources 414, 393-400 (2019) describes a sample of n-type Mg_{3.1}Co_{0.1}Sb_{1.5}Bi_{0.49} Te_{0.01}. This sample is produced by placing a powder of a thermoelectric conversion material on a graphite die in a state in which the powder of the thermoelectric conversion material is held by a powder of iron and pressing these powders under heating.

Yin et al., Acta Materialia 198, 25-34 (2020) describes joining of n-type Mg_{3.2}Sb_{1.5}Bi_{0.49}Te_{0.01} and stainless steel (SUS304).

Japanese Unexamined Patent Application Publication No. 2009-260173 describes a thermoelectric conversion element in which a pair of electrode layers formed of a metal material are formed on both sides of a thermoelectric conversion layer formed of magnesium silicide. In this thermoelectric conversion element, buffer layers each formed of a mixture of magnesium silicide and a metal material are formed between the thermoelectric conversion layer and the electrode layers. The metal material is a nickel-based material.

### SUMMARY

The present disclosure provides a thermoelectric conversion element that is advantageous from the viewpoint of inhibiting an increase in electric resistance in high-temperature air.

In one general aspect, the techniques disclosed here feature a thermoelectric conversion element including a first metal layer and a thermoelectric convertor containing Mg and at least one selected from the group consisting of Sb and Bi, wherein the thermoelectric convertor includes a thermoelectric conversion layer and a first joining layer disposed between the first metal layer and the thermoelectric conversion layer in a thickness direction of the thermoelectric conversion layer, the first joining layer contains at least one selected from the group consisting of Fe and Ni, and the first joining layer satisfies a first condition represented by 2.5≤α/β≤6.5, where α is a content of Mg in terms of number of atoms in the first joining layer, and β is a sum of contents of Sb and Bi in terms of number of atoms in the first joining layer.

The present disclosure provides a thermoelectric conversion element that is advantageous from the viewpoint of inhibiting an increase in electric resistance in high-temperature air.

It should be noted that general or specific embodiments may be implemented as a system, a method, an integrated circuit, a computer program, a storage medium, or any selective combination thereof.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a cross-sectional view schematically illustrating a thermoelectric conversion element of a first embodiment;

FIG. 2 is a flowchart of a method for producing the thermoelectric conversion element of the first embodiment;

FIG. 3 is a cross-sectional view schematically illustrating an example of a thermoelectric conversion element of a second embodiment;

FIG. 4 is a cross-sectional view schematically illustrating another example of the thermoelectric conversion element of the second embodiment;

FIG. 5 is a perspective view of a thermoelectric conversion module of a third embodiment;

FIG. 6 is a side view of a thermoelectric conversion system of a fourth embodiment;

FIG. 7 is a scanning electron microscope image of a cross section of a joint portion of a thermoelectric conversion element according to Example 1; and

FIG. 8 is a scanning electron microscope image of a cross section of a joint portion of a thermoelectric conversion element according to Example 6.

### DETAILED DESCRIPTIONS

### Underlying Knowledge Forming Basis of the Present Disclosure

A thermoelectric conversion technique in which heat energy is converted into electric energy by a solid element to generate electric power is widely known. It is proposed that an n-type thermoelectric conversion element and a p-type thermoelectric conversion element are connected to each other on a substrate electrically in series and thermally in parallel to configure a plate-like thermoelectric conversion module. By applying a temperature difference to this thermoelectric conversion module, electric power is generated. To achieve good electric connection in the thermoelectric conversion module, it is proposed that a thermoelectric conversion element in which a thermoelectric conversion material is subjected to metal plating or a thermoelectric conversion element in which a metal powder or a metal plate is joined to a thermoelectric conversion material by a method such as sintering is used. When electric power is generated by the thermoelectric conversion element, the thermoelectric conversion element may be placed in a high-temperature air (for example, air at 400° C.) environment for a long period of time. Even in such a case, it is important that an increase in electric resistance be inhibited in the thermoelectric conversion element.

Although Japanese Patent No. 6127281 describes a thermoelectric conversion material represented by Mg₃₊ₘAₐB_{b}D₂₋ₑEₑ, it does not describe the configuration of a thermoelectric conversion element containing the thermoelectric conversion material.

Tamaki et al., Advanced Materials 28, 10182-10187 (2016) states that it is required that excessive Mg with respect to the stoichiometric ratio be present in order to increase the thermoelectric conversion performance of the n-type Mg_{3+δ} (Sb,Bi) thermoelectric conversion material. Meanwhile, according to a study by the present inventor, Mg easily oxidizes and has high vapor pressure, and in a high-temperature air environment, Mg in a thermoelectric conversion material containing Mg and at least one selected from the group consisting of Sb and Bi is easily lost due to the oxidization or sublimation of Mg. Consequently, there arises a problem in that when such a thermoelectric conversion material is placed in a high-temperature air environment for a long time, the electric resistance of the thermoelectric conversion element rises, and the thermoelectric conversion performance easily decreases. The present inventor has focused on this problem.

The present inventor has intensively studied a configuration in which the electric resistance of the thermoelectric conversion element containing the thermoelectric conversion material containing Mg and at least one selected from the group consisting of Sb and Bi is less likely to rise in high-temperature air.

Zhu et al., Journal of Power Sources 414, 393-400 (2019) describes a sample produced by placing a powder of a thermoelectric conversion material on a graphite die in a state in which the powder of the thermoelectric conversion material is held by a powder of iron and pressing these powders under heating. In addition, Yin et al., Acta Materialia 198, 25-34 (2020) describes the joining of n-type Mg_{3.2}Sb_{1.5}Bi_{0.49}Te_{0.01} and stainless steel (SUS304). In a reproduced experiment by the present inventor on the samples described in Zhu et al., Journal of Power Sources 414, 393-400 (2019) and Yin et al., Acta Materialia 198, 25-34 (2020), it has been revealed that there are variations in the initial characteristics of the reproduced samples and that the electric resistance of the samples rises in high-temperature air.

In the thermoelectric conversion element described in Japanese Unexamined Patent Application Publication No. 2009-260173, buffer layers each formed of a mixture of magnesium silicide and a metal material are formed between a thermoelectric conversion layer formed of magnesium silicide and electrode layers. However, excessive Mg with respect to the stoichiometric ratio is not present in this thermoelectric conversion element, and Japanese Unexamined Patent Application Publication No. 2009-260173 does not provide any knowledge for solving the problem about the thermoelectric conversion element described above.

The present inventor, after much trial and error, has newly found that when a predetermined joining layer is disposed between a metal layer and a layer containing a thermoelectric conversion material, the electric resistance of the thermoelectric conversion element is less likely to rise in high-temperature air. Based on this knowledge, the present inventor has completed the thermoelectric conversion element according to the present disclosure.

### EMBODIMENTS OF THE PRESENT DISCLOSURE

Embodiments of the present disclosure will be described below with reference to the drawings.

### First Embodiment

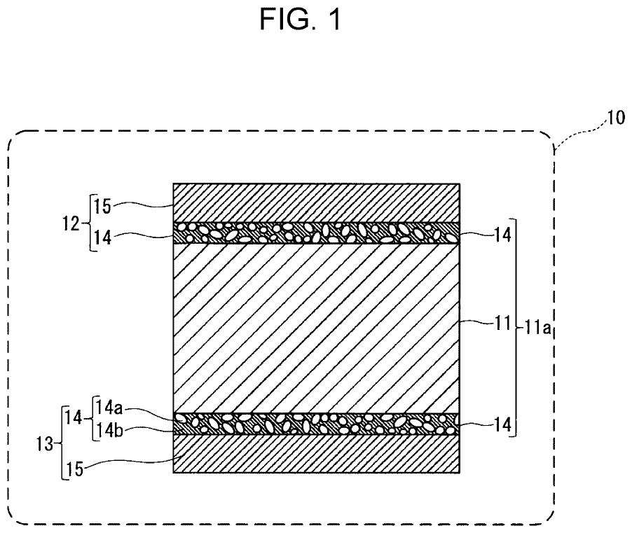

FIG. 1 is a cross-sectional view schematically illustrating a thermoelectric conversion element of a first embodiment. As illustrated in FIG. 1, a thermoelectric conversion element 10 includes first metal layers 15 and a thermoelectric convertor 11a. The thermoelectric convertor 11a contains Mg and at least one selected from the group consisting of Sb and Bi. The thermoelectric convertor 11a includes a thermoelectric conversion layer 11 and first joining layers 14. The first joining layers 14 contain at least one selected from the group consisting of Fe and Ni. The first joining layers 14 satisfy a condition of 2.5≤α/β≤6.5. In this condition, a is the content of Mg in terms of number of atoms in the first joining layers 14, and B is the sum of the contents of Sb and Bi in terms of number of atoms in the first joining layers 14. When the first joining layers 14 are thus configured, even if the thermoelectric conversion element 10 is placed in a high-temperature air (for example, air at 400° C.) environment, an increase in the electric resistance of the thermoelectric conversion element 10 is easily inhibited. The present inventor believes that even if the thermoelectric conversion element 10 is placed in a high-temperature air environment, Mg is less likely to be lost from a thermoelectric conversion material contained in the thermoelectric conversion layer 11 owing to the first joining layers 14.

The first joining layers 14 may satisfy a condition of α/β≥2.6, satisfy a condition of α/β≥2.8, or satisfy a condition of α/β≥3.0.

As illustrated in FIG. 1, the first joining layers 14 are disposed, for example, between the thermoelectric conversion layer 11 and the first metal layers 15 in the thickness direction of the first joining layers 14. One principal surface (a first principal surface) of each first joining layer 14 is in contact with the thermoelectric conversion layer 11, and the other principal surface (a second principal surface) of the first joining layer 14 is in contact with the first metal layer 15.

So long as the condition of 2.5≤α/β≤6.5 is satisfied, a is not limited to a particular value. For example, a condition of 18%≤α≤32% may be satisfied, a condition of 18%≤α≤30% may be satisfied, or a condition of 19%≤α≤30% may be satisfied.

So long as the condition of 2.5≤α/β≤6.5 is satisfied, β is not limited to a particular value. For example, a condition of 3%≤β≤15% may be satisfied, a condition of 4%≤β≤12% may be satisfied, or a condition of 4%≤β≤10% may be satisfied.

The structure of the first joining layers 14 is not limited to a particular structure so long as they contain at least one selected from the group consisting of Fe and Ni and satisfy the condition of 2.5≤α/β≤6.5. As illustrated in FIG. 1, the first joining layers 14 include, for example, particles 14a and a phase 14b forming a solid phase different from the particles 14a. The particles 14a contain at least one selected from the group consisting of Fe and Ni. The phase 14b is present among the particles 14a. In addition, the phase 14b contains Mg. With such a structure, even if the thermoelectric conversion element 10 is placed in a high-temperature air environment, the increase in the electric resistance of the thermoelectric conversion element 10 is more easily inhibited.

The phase 14b may be a continuous phase or a dispersed phase. The melting point of the phase 14b is, for example, lower than the melting point of the particles 14a.

A sum γ of the contents of Fe and Ni in terms of number of atoms in the first joining layers 14 is not limited to a particular value. The first joining layers 14 satisfy, for example, a condition of γ≥65%. With such a configuration, the electric resistance of the thermoelectric conversion element 10 is less likely to increase. In addition, the joining strength between the thermoelectric conversion layer 11 and the first metal layers 15 easily increases.

The first joining layers 14 may satisfy a condition of γ≥66%, satisfy a condition of γ≥67%, or satisfy a condition of γ≥68%. The first joining layers 14 satisfy, for example, a condition of γ≤80%.

In the first joining layers 14, a ratio α/γ is not limited to a particular value. The first joining layers 14 satisfy, for example, a condition of 0.002<α/γ<0.6. With such a configuration, even if the thermoelectric conversion element 10 is placed in a high-temperature air environment, the increase in the electric resistance of the thermoelectric conversion element 10 is more easily inhibited. In addition, the joining strength between the thermoelectric conversion layer 11 and the first metal layers 15 easily increases.

In the first joining layers 14, α/γ may fall in a range defined by a pair of values selected from the group consisting of 0.005, 0.01, 0.05, 0.1, 0.2, 0.3, 0.4, and 0.5.

As illustrated in FIG. 1, for example, the thermoelectric conversion layer 11 is disposed between a first composite metal layer 12 and a second composite metal layer 13 in the thickness direction of the thermoelectric conversion layer 11. Each of the first composite metal layer 12 and the second composite metal layer 13 includes the first joining layer 14 and the first metal layer 15.

The three-dimensional shape of the thermoelectric conversion element 10 is not limited to a particular shape. The thermoelectric conversion element 10 may have a rectangular parallelepiped shape. In this case, a cross section of the thermoelectric conversion element 10 perpendicular to the page of FIG. 1 is a rectangle or square. The thermoelectric conversion element 10 may be cylindrical. In this case, a cross section of the thermoelectric conversion element 10 perpendicular to the page of FIG. 1 is a circle. The thermoelectric conversion element 10 may have an irregular shape in a cross section of the thermoelectric conversion element 10 perpendicular to the page of FIG. 1.

The thickness of each layer of the thermoelectric conversion element 10 is not limited to a particular value. The thickness of the thermoelectric conversion layer 11 is, for example, greater than or equal to 0.5 mm and less than or equal to 10 mm. The thickness of the first joining layers 14 is, for example, greater than or equal to 0.01 mm and less than or equal to 0.2 mm. The thickness of the first metal layers 15 is, for example, greater than or equal to 0.05 mm and less than or equal to 1 mm. It is advantageous that the thickness of each layer be within such a range from the viewpoints of the production costs of the thermoelectric conversion element 10 and workability in the production of the thermoelectric conversion element 10.

The cross-sectional view illustrated in FIG. 1 is schematic. A plurality of interfaces formed by individual parts forming a layered structure may or do not have to be parallel to each other. The interfaces may have unevenness. The external shape of a cross section may be a rectangle, and the sides of the external shape of a cross section may have unevenness or curve. A pair of sides adjacent to each other in the external shape of a cross section may cross each other at a right angle or cross each other so as to form an angle less than 90° or an angle greater than 90° and less than 180°.

The thermoelectric conversion material contained in the thermoelectric conversion layer 11 is not limited to a particular material so long as it contains Mg and at least one selected from the group consisting of Sb and Bi. The thermoelectric conversion layer 11 contains, for example, an n-type thermoelectric conversion material having a La₂O₃ type crystal structure and having a composition of Mg₃₊ₘAₐD₂₋ₑEₑ. In this composition, the element A is at least one element selected from the group consisting of La, Y, Yb, Mn, and Zn. The element D is at least one element selected from the group consisting of Sb and Bi. The element E is at least one element selected from the group consisting of Te and Se. The value of m is greater than or equal to −0.1 and less than or equal to 0.4. The value of a is greater than or equal to 0 and less than or equal to 0.1. The value of e is greater than or equal to 0.001 and less than or equal to 0.06.

The thermoelectric conversion layer 11 may contain an element of the same type as any of the elements contained in the first joining layers 14. For example, the thermoelectric conversion layer 11 can contain an element, derived from the raw material of the first joining layers 14, of the same type as any of the elements contained in the first joining layers 14.

The particles 14a may contain only one of Fe and Ni or contain both Fe and Ni. The particles 14a may contain elemental Fe or contain elemental Ni. The particles 14a may contain an alloy containing at least one selected from the group consisting of Fe and Ni. For example, the particles 14a may contain an iron-based alloy such as stainless steel or contain a nickel-based alloy such as Inconel or Hastelloy. Inconel and Hastelloy are registered trademarks. The particles 14a may contain metals other than Fe and Ni. The particles 14a may contain, for example, metals such as Cr and Mo.

The particles 14a may contain an element of the same type as any of the elements contained in the thermoelectric conversion layer 11 or the phase 14b. For example, the particles 14a can contain an element, derived from the raw material of the thermoelectric conversion layer 11 or the raw material of the phase 14b, of the same type as any of the elements contained in the thermoelectric conversion layer 11 or the phase 14b.

An average particle size q of the particles 14a is not limited to a particular value. The average particle size q satisfies, for example, a condition of 0.5 μm≤q≤100 μm. In this case, the joining strength between the thermoelectric conversion layer 11 and the first metal layers 15 easily increases. The average particle size q is, for example, the median size d50 in volume-based particle size distribution obtained by laser diffraction type particle size distribution measurement.

The phase 14b may contain an element of the same type as any of the elements contained in the thermoelectric conversion layer 11 or the particles 14a. For example, the phase 14b can contain an element, derived from the raw material of the thermoelectric conversion layer 11 or the raw material of the particles 14a, of the same type as any of the elements contained in the thermoelectric conversion layer 11 or the particles 14a.

The metal contained in the first metal layers 15 is not limited to a particular metal. The first metal layers 15 contain, for example, at least one selected from the group consisting of Fe, Ni, Cu, and Ag. In this case, the electric resistance of the thermoelectric conversion element 10 is easily lowered.

The first metal layers 15 may contain elemental Fe, contain elemental Ni, contain elemental Cu, or contain elemental Ag. The first metal layers 15 may contain an alloy. Examples of the alloy include stainless steel, Inconel, and Hastelloy. The first metal layers 15 may contain oxygen-free copper.

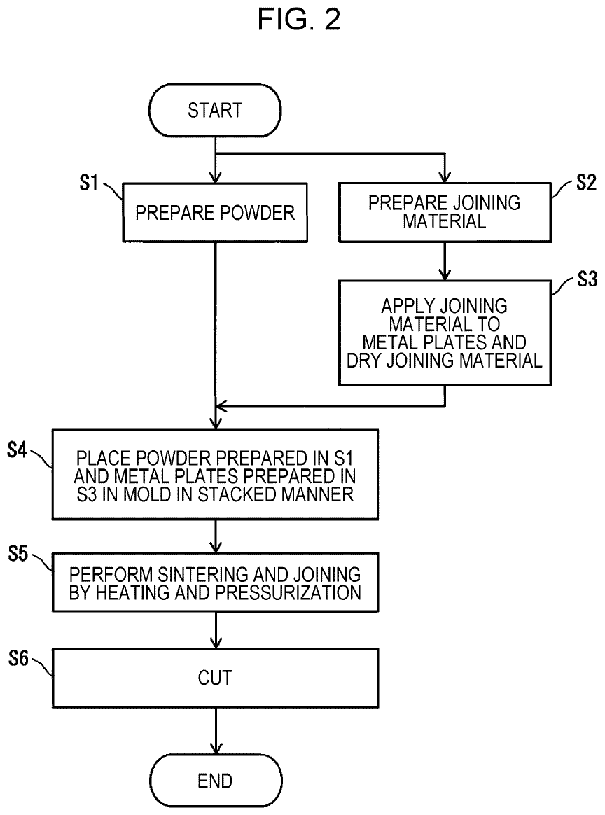

The following describes an example of a method for producing the thermoelectric conversion element 10. FIG. 2 is a flowchart of a method for producing the thermoelectric conversion element of the first embodiment. This method of production includes, for example, heating a metal plate, a powder, and a joining material in a predetermined state to sinter the powder and to join together the metal plate and a sintered body of the powder. The predetermined state is a state in which the joining material is disposed between the metal plate and the powder in the thickness direction of the metal plate. The joining material contains Mg and at least one selected from the group consisting of Fe and Ni. The powder contains Mg and at least one selected from the group consisting of Sb and Bi.

As illustrated in FIG. 2, in Step S1, the powder is prepared. The powder is prepared in accordance with, for example, a known method for producing a powder using an arc melting method and a ball mill for a raw material weighed in a predetermined amount. The powder may be prepared with reference to the methods described in Tamaki et al., Advanced Materials 28, 10182-10187 (2016), Zhu et al., Journal of Power Sources 414, 393-400 (2019), and Yin et al., Acta Materialia 198, 25-34 (2020). The powder is, for example, a powder of the thermoelectric conversion material described above.

In Step S2, the joining material is prepared. As described above, the joining material contains Mg and at least one selected from the group consisting of Fe and Ni and can join together the thermoelectric conversion material and a metal member.

The joining material is, for example, a paste composition. The joining material is prepared by, for example, mixing together a high-melting-point metal-containing powder as the raw material of the particles 14a, a low-melting-point Mg-containing powder as the raw material of the phase 14b, an organic binder, and an organic solvent. The high-melting-point metal-containing powder contains, for example, at least one selected from the group consisting of Fe and Ni. This metal powder may be a powder of elemental Fc, a powder of elemental Ni, or a powder of an alloy containing at least one selected from the group consisting of Fe and Ni. Examples of the alloy include stainless steel, Inconel, and Hastelloy. The low-melting-point Mg-containing powder may be a powder of elemental Mg or a powder of an alloy containing Mg. Examples of the alloy include alloys of Mg and Cu.

An average particle size p of particles contained in the metal-containing powder is not limited to a particular value. The average particle size p satisfies, for example, a condition of 0.5 μm≤p≤100 μm. This easily increases the joining strength between the thermoelectric conversion material and the metal member. The average particle size p is, for example, the median size d50 in volume-based particle size distribution obtained by laser diffraction type particle size distribution measurement.

The average particle size p may satisfy a condition of 1 μm≤p≤50 μm, satisfy a condition of 2 μm≤p≤50 μm, or satisfy a condition of 5 μm≤p≤30 μm.

The ratio of the content of the high-melting-point metal-containing powder in the joining material to the content of the Mg-containing powder in the joining material is, for example, greater than or equal to 97/3 and less than or equal to 99.5/0.5 on a mass basis. With this, even if the produced thermoelectric conversion element 10 is placed in a high-temperature air environment, the increase in the electric resistance of the thermoelectric conversion element 10 is more easily inhibited. In addition, in the production of the thermoelectric conversion element 10, Mg melted from the Mg-containing powder is prevented from leaking to the outside, and the diffusion of Mg toward the thermoelectric conversion material is prevented from becoming conspicuous. Consequently, the thermoelectric conversion element 10 is easily stably produced.

The organic binder contained in the joining material is not limited to a particular organic binder. The organic binder has a characteristic of, for example, evaporating and decomposing in the production of the thermoelectric conversion element 10 and being less likely to remain in the thermoelectric conversion element 10. The organic binder is, for example, a butyl rubber-based resin or acrylic resin. The organic solvent dissolves or disperses the organic binder. The organic solvent is, for example, a naphthene-based hydrocarbon solvent or toluene.

In the preparation of the joining material, prior to the addition of the metal-containing powder, a binder solution in which the organic binder has been dissolved or dispersed in the organic solvent in advance may be prepared. The concentration of the organic binder in the binder solution is, for example, greater than or equal to 1% by mass and less than or equal to 15% by mass. In this case, the joining material easily has a viscosity suitable for application. The ratio of the mass of the metal-containing powder to the mass of the binder solution in the joining material is, for example, 3/2 to 9. In this case, the joining material easily has a viscosity suitable for application.

In Step S3, the joining material is applied to metal plates and dried. The method for applying the joining material to the metal plates is not limited to a particular method. The method is, for example, doctor blading. The organic solvent is evaporated during the drying of the joining material to obtain a dry coating. The drying of the joining material can be performed using a hot plate or oven. This provides precursors of the first composite metal layer 12 and the second composite metal layer 13. The metal plates are, for example, discs.

In Step S4, the powder prepared in Step S1 and the precursors of the first composite metal layer 12 and the second composite metal layer 13 prepared in Step S3 are placed in a cylindrical sintering mold made of carbon in accordance with the arrangement illustrated in FIG. 1. In other words, the powder and the precursors of the first composite metal layer 12 and the second composite metal layer 13 are disposed such that the joining material is disposed between the metal plates and the powder in the thickness direction of the metal plates. The metal plates have, for example, a diameter less than or equal to the inner diameter of the sintering mold. Subsequently, the sintering mold is held between punches in the thickness direction of the metal plates.

In Step S5, the sintering of the powder and the joining of the sintered body of the powder and the metal plates are performed in a state in which pressure is applied to the punches to pressurize the inside of the sintering mold. This provides a stacked body in which the sintered body of the powder and the metal plates are joined together. The sintering of the powder may be performed in accordance with an electric heating type method such as a discharge plasma sintering method or performed in accordance with a hot press method accompanied by heating by an electric heater or high-frequency heating. The sintering of the powder is performed, for example, in an argon atmosphere with a low oxygen partial pressure or a vacuum. This makes the thermoelectric conversion material contained in the powder less likely to oxidize. The sintering of the powder is desirably performed in an argon atmosphere. In this case, Mg is less likely to evaporate.

The sintering temperature of the powder is, for example, higher than or equal to the melting point of Mg, i.e., higher than or equal to 650° C. When the first metal layers 15 contain at least one selected from the group consisting of Fe and Ni, the sintering temperature of the powder may be adjusted to be about 900° C. On the other hand, when the first metal layers 15 contain Cu or Ag, the sintering temperature of the powder can be adjusted to lower than or equal to 720° C. This can prevent the metal component contained in the first metal layers 15 from fusing and melting with Mg.

In Step S6, the stacked body obtained in Step S5 is taken out of the sintering mold, and the cutting of the stacked body provides the thermoelectric conversion element 10 having a rectangular parallelepiped shape. The method for cutting the stacked body is not limited to a particular method. For example, the stacked body can be cut using a diamond cutter or wire saw.

### Second Embodiment

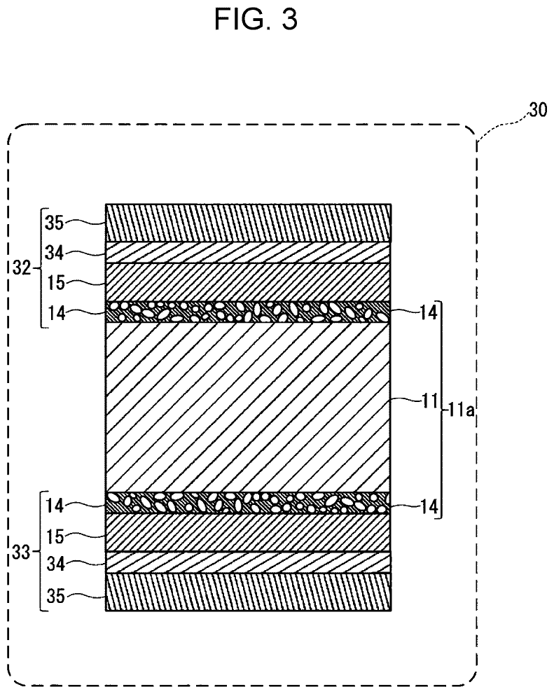

FIG. 3 is a cross-sectional view schematically illustrating an example of a thermoelectric conversion element of a second embodiment. The thermoelectric conversion element of the second embodiment is configured in the same manner as the thermoelectric conversion element of the first embodiment except parts particularly described. The components of the thermoelectric conversion element of the second embodiment that are the same as or corresponding to the components of the thermoelectric conversion element of the first embodiment are denoted by the same numerals, and detailed descriptions thereof are omitted. The description about the thermoelectric conversion element of the first embodiment also applies to the second embodiment so long as there is no technical contradiction.

As illustrated in FIG. 3, a thermoelectric conversion element 30 further includes second metal layers 35 in addition to the first metal layers 15 and the thermoelectric convertor 11a. The second metal layers 35 contain at least one selected from the group consisting of Cu and Ag. The first metal layers 15 are disposed between the second metal layers 35 and the thermoelectric convertor 11a in the thickness direction of the first metal layers 15. In addition, the first metal layers 15 contain at least one selected from the group consisting of Fe and Ni. With such a configuration, when a thermoelectric conversion module is produced using a plurality of thermoelectric conversion elements 30, work for electric connection between the thermoelectric conversion element 30 and another thermoelectric conversion element adjacent to the thermoelectric conversion element 30 is easily performed. In addition, even when the second metal layers 35 are disposed at ends of the thermoelectric conversion element 30 in the thickness direction of the first metal layers 15, the temperature for joining the first metal layers 15 and the second metal layers 35 to the thermoelectric convertor 11a can be raised up to about 900° C.

In the thermoelectric conversion element 30, the first metal layers 15 may contain elemental Fe, contain elemental Ni, or contain an alloy containing at least one selected from the group consisting of Fe and Ni. Examples of the alloy include stainless steel, Inconel, and Hastelloy.

In the thermoelectric conversion element 30, the second metal layers 35 contain, for example, Cu or Ag.

As illustrated in FIG. 3, the thermoelectric conversion element 30 further includes, for example, second joining layers 34. The second joining layers 34 are disposed between the first metal layers 15 and the second metal layers 35 in the thickness direction of the second joining layers 34. The second joining layers 34 contain, for example, at least one selected from the group consisting of Cu and Ag. The second joining layers 34 may contain elements such as Mg, Sn, Ti, and Al. For example, the content of each of Mg, Sn, Ti, and Al in the second joining layers 34 is less than or equal to 1% by mass.

As illustrated in FIG. 3, for example, the thermoelectric conversion layer 11 is disposed between a first composite metal layer 32 and a second composite metal layer 33 in the thickness direction of the thermoelectric conversion layer 11. Each of the first composite metal layer 32 and the second composite metal layer 33 includes the first joining layer 14, the first metal layer 15, the second joining layer 34, and the second metal layer 35.

The thermoelectric conversion element 30 can be produced, for example, in the same manner as the thermoelectric conversion element 10. The raw material of the second joining layers 34 is, for example, a paste composition containing a metal component. The raw material of the second metal layers 35 is, for example, a metal plate.

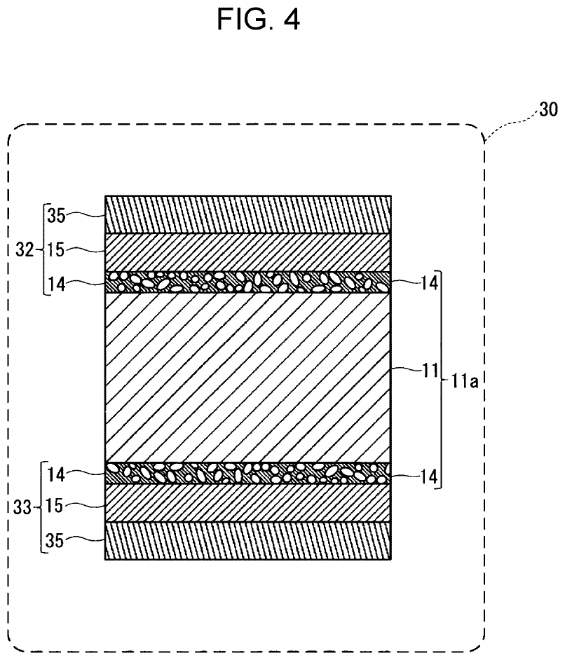

FIG. 4 is a cross-sectional view schematically illustrating another example of the thermoelectric conversion element of the second embodiment. For example, when the second joining layers 34 and the second metal layers 35 contain the same type of metal, the boundaries between the second joining layers 34 and the second metal layers 35 may be unclear in a cross section of the thermoelectric conversion element 30. For example, when both the second joining layers 34 and the second metal layers 35 contain Cu or Ag, the boundaries between them are unclear, and the second joining layers 34 and the second metal layers 35 look like a single layer. In this case, as illustrated in FIG. 4, the parts looking like a single layer may be regarded as the second metal layers 35.

### Third Embodiment

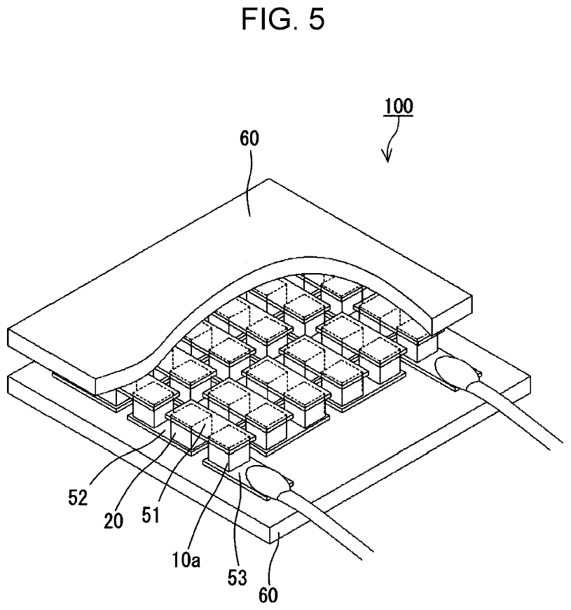

FIG. 5 is a perspective view of an example of a thermoelectric conversion module of a third embodiment. As illustrated in FIG. 5, a thermoelectric conversion module 100 includes p-type thermoelectric conversion bodies 20, n-type thermoelectric conversion bodies 10a, and first electrodes 51. The n-type thermoelectric conversion bodies 10a each include the thermoelectric conversion element 10 or the thermoelectric conversion element 30. The thermoelectric conversion material contained in the p-type thermoelectric conversion bodies 20 is not limited to a particular material, and, for example, a known p-type thermoelectric conversion material is contained. The first electrodes 51 electrically connects ends of the p-type thermoelectric conversion bodies 20 and ends of the n-type thermoelectric conversion bodies 10a to each other. With such a configuration, even if the thermoelectric conversion module 100 is placed in a high-temperature air environment, an increase in the electric resistance of the thermoelectric conversion elements 10 or the thermoelectric conversion elements 30 included in the n-type thermoelectric conversion bodies 10a is easily inhibited.

As illustrated in FIG. 5, the thermoelectric conversion module 100 further includes, for example, second electrodes 52 and third electrodes 53. The second electrodes 52 are electrically connected to the other ends of the p-type thermoelectric conversion bodies 20. The third electrodes 53 are electrically connected to the other ends of the n-type thermoelectric conversion bodies 10a.

The thermoelectric conversion module 100 further includes, for example, a pair of substrates 60. One of the pair of substrates 60 is disposed in contact with the first electrodes 51, and the other of the pair of substrates 60 is disposed in contact with the second electrodes 52 and the third electrodes 53. With this configuration, variations in temperature in a direction parallel to principal surfaces of the substrates 60 are less likely to occur in the thermoelectric conversion module 100. The material of the substrates 60 is not limited to a particular material. The substrates 60 contain, for example, alumina or aluminum nitride.

### Fourth Embodiment

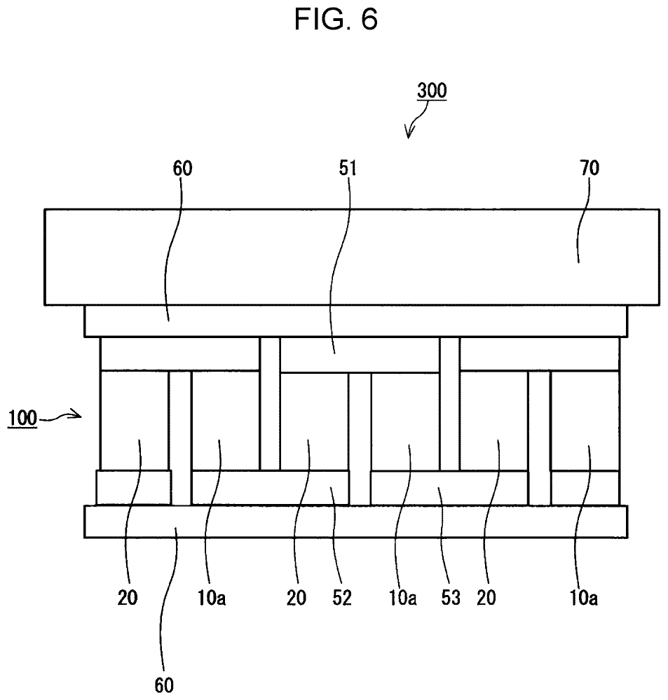

FIG. 6 is a side view of a thermoelectric conversion system of a fourth embodiment. As illustrated in FIG. 6, a thermoelectric conversion system 300 includes the thermoelectric conversion module 100 and a heat source 70. The heat source 70 is disposed on a side closer to the first electrodes 51 of the thermoelectric conversion module 100.

The thermoelectric conversion system 300 can generate electric power by causing a temperature difference in the thermoelectric conversion module 100 using heat from the heat source 70.

In the thermoelectric conversion system 300, the heat source 70 may include a heat conduction pipe, and a predetermined heat medium is introduced into the heat conduction pipe. The heat medium may be a gas such as exhaust gas or a liquid such as water or oil. The heat source 70 may include a plate member for collecting radiant heat.

As illustrated in FIG. 6, for example, in the thermoelectric conversion system 300, one of the pair of substrates 60 of the thermoelectric conversion module 100 is disposed between the heat source 70 and the thermoelectric conversion module 100.

### APPENDIX

The following techniques are disclosed by the above description.

### Technique 1

A thermoelectric conversion element including:
a first metal layer; and
a thermoelectric convertor containing Mg and at least one selected from the group consisting of Sb and Bi, wherein
the thermoelectric convertor includes:
   a thermoelectric conversion layer; and
   a first joining layer disposed between the first metal layer and the thermoelectric conversion layer in a thickness direction of the thermoelectric conversion layer,
the first joining layer contains at least one selected from the group consisting of Fe and Ni, and
the first joining layer satisfies a first condition represented by 2.5≤α/β≤6.5,
where
α is a content of Mg in terms of number of atoms in the first joining layer, and
β is a sum of contents of Sb and Bi in terms of number of atoms in the first joining layer.

### Technique 2

The thermoelectric conversion element according to Technique 1, wherein
the first joining layer includes particles containing at least one selected from the group consisting of Fe and Ni and a phase present among the particles and forming a solid phase different from the particles, and
the phase contains Mg.

### Technique 3

The thermoelectric conversion element according to Technique 1 or 2, wherein
the first joining layer satisfies a second condition represented by 0.002<α/γ<0.6, wherein γ is a sum of contents of Fe and Ni in terms of number of atoms in the first joining layer in the second condition.

### Technique 4

The thermoelectric conversion element according to any one of Techniques 1 to 3, wherein
a sum γ of contents of Fe and Ni in terms of number of atoms in the first joining layer satisfies a third condition of γ≥65%.

### Technique 5

The thermoelectric conversion element according to any one of Techniques 1 to 4, wherein
the first metal layer contains at least one selected from the group consisting of Fe, Ni, Cu, and Ag.

### Technique 6

The thermoelectric conversion element according to any one of Techniques 1 to 5, further including:
a second metal layer containing at least one selected from the group consisting of Cu and Ag,
wherein
the first metal layer is disposed between the second metal layer and the thermoelectric convertor in a thickness direction of the first metal layer and contains at least one selected from the group consisting of Fe and Ni.

### Technique 7

A joining material containing Mg and at least one selected from the group consisting of Fe and Ni, wherein the joining material is capable of joining together a thermoelectric conversion material and a metal member.

### Technique 8

A thermoelectric conversion module including:
a p-type thermoelectric conversion body;
an n-type thermoelectric conversion body; and
an electrode electrically connecting one end of the p-type thermoelectric conversion body and one end of the n-type thermoelectric conversion body to each other,
wherein
the n-type thermoelectric conversion body includes the thermoelectric conversion element according to any one of Techniques 1 to 7.

### Technique 9

A thermoelectric conversion system including:
the thermoelectric conversion module according to Technique 8; and
a heat source disposed on a side closer to the electrode.

### Technique 10

A method for generating electric power, including:
causing a temperature difference in the thermoelectric conversion module according to Technique 8 using heat from a heat source to generate electric power.

### Technique 11

A method for producing a thermoelectric conversion element, the method including:
heating a metal plate, a powder, and a joining material in a state in which the joining material is disposed between the metal plate and the powder in a thickness direction of the metal plate to sinter the powder and to join together the metal plate and a sintered body of the powder,
wherein
the joining material contains Mg and at least one selected from the group consisting of Fe and Ni, and
the powder contains Mg and at least one selected from the group consisting of Sb and Bi.

### Technique 12

The method of production according to Technique 11, wherein
the joining material contains particles containing at least one selected from the group consisting of Fe and Ni, and
an average particle size p of the particles satisfies a fourth condition represented by 0.5 μm≤p≤100 μm.

### EXAMPLES

The present disclosure will be described below in detail with reference to examples. However, the thermoelectric conversion material of the present disclosure is not limited to specific aspects described below.

### Example 1

Raw material powders were weighed in a glove box with an argon atmosphere to weigh 2.00 g of a Mg powder, 4.70 g of an Sb powder, 2.63 g of a Bi powder, and 0.03 g of a Te powder. The weighed raw material powders were sealed in an ultrahard steel container manufactured by SPEX Sample Prep, Model 8001, together with ultrahard steel balls. Subsequently, the raw material powders sealed in the container were mixed together using a shake mill apparatus manufactured by SPEX Sample Prep, Model 8000D, for 2 hours to produce a powder of a thermoelectric conversion material by a mechanochemical reaction. Thus, a powder of a thermoelectric conversion material having a composition of Mg_{3.2}Sb_{1.5}Bi_{0.49}Te_{0.01} and having a La₂O₃ type crystal structure was obtained.

A naphthene-based hydrocarbon solvent in an amount of 90 g was weighed out in a beaker, and a total of 10 g of a butyl rubber-based binder was added thereto in small portions with stirring using a stirrer to prepare a 10% by weight binder solution. In a polyethylene container, 6.93 g of a stainless steel powder (a powder of SUS304), 0.07 g of a Mg powder, and 3.0 g of the binder solution were put. The ratio of the amount of the stainless steel powder added to the amount of the Mg powder added was 99.0 on a mass basis. According to the volume-based particle size distribution of the stainless steel powder obtained by laser diffraction type particle size distribution measurement, the particle size of the stainless steel powder was in a range of 1 μm to 50 μm. In addition, the average particle size (the median size d50) of the stainless steel powder was about 10 μm. The contents of this container were mixed by shaking with a shake mill apparatus for 6 minutes to obtain a paste joining material according to Example 1.

The joining material according to Example 1 was applied to one principal surface of a disc made of stainless steel having a diameter of 19.9 mm and a thickness of 0.2 mm to form a coating of the joining material having a thickness of 0.1 mm.

The disc made of stainless steel on which the coating of the joining material was formed was placed on a hot plate heated to 120° C. to dry the joining material for 15 minutes. In this way, two stainless steel plates with the joining material were obtained.

In a glove box with an argon atmosphere, members were placed in a sintering mold made of carbon having an inner diameter of 20 mm in the following order. Here, the two stainless steel plates with the joining material were disposed such that the coating of the joining material was in contact with the powder of the thermoelectric conversion material.

A punch made of carbon having an outer diameter of 20 mm

A carbon sheet having a diameter of 20 mm

A first stainless steel plate with the joining material

The powder of the thermoelectric conversion material in an amount of 5.0 g

A second stainless steel plate with the joining material

A carbon sheet having a diameter of 20 mm

A punch made of carbon having an outer diameter of 20 mm

The sintering mold in which the raw materials were placed was installed inside the chamber of a discharge plasma sintering apparatus manufactured by SPS Syntex Inc., SPS-515S, and the environment of the sintering mold was adjusted to an argon atmosphere. The sintering mold was heated up to 850° C. while applying a pressure of 50 MPa to the inside of the sintering mold to perform the sintering of the powder of the thermoelectric conversion material and the joining of the powder of the thermoelectric conversion material and the stainless steel plates.

Next, the sintering mold was cooled to room temperature through the furnace cooling of the sintering mold, then the contents inside the sintering mold were taken out, and the contents were polished with abrasive paper to remove the carbon sheets from the contents and obtain a stacked body according to Example 1.

The stacked body according to Example 1 was cut with a diamond cutter to obtain thermoelectric conversion elements according to Example 1 having a rectangular parallelepiped shape with a size of 3.4 mm×3.4 mm×3.5 mm. Twelve thermoelectric conversion elements were obtained.

### Measurement of Electric Resistance

Using a current source manufactured by Keithley, Model 6221, and a voltmeter manufactured by Keithley, Model 2182A, the electric resistance between the pair of stainless steel plates of each thermoelectric conversion element according to Example 1 was measured in accordance with a four-terminal method. As listed in Table 1, the average of the electric resistance of three thermoelectric conversion elements was 6 mΩ. The thermoelectric conversion elements of Example 1 were put in a box type electric furnace from Tokyo Garasu Kikai Co., Ltd., Model F-1404-P, set at 400° C. and were placed in an air environment at 400° C. for 4 days to perform heat treatment. Next, after the electric furnace was returned to room temperature, the thermoelectric conversion elements were taken out, and the surfaces of the stainless steel plates were polished with abrasive paper to remove oxide films from the surfaces. Subsequently, the electric resistance between the pair of stainless steel plates of each thermoelectric conversion element was measured in accordance with the four-terminal method. Consequently, the average of the electric resistance of the three thermoelectric conversion elements after the heat treatment was 6.2 mΩ.

### Cross-Sectional Observation of Thermoelectric Conversion Element

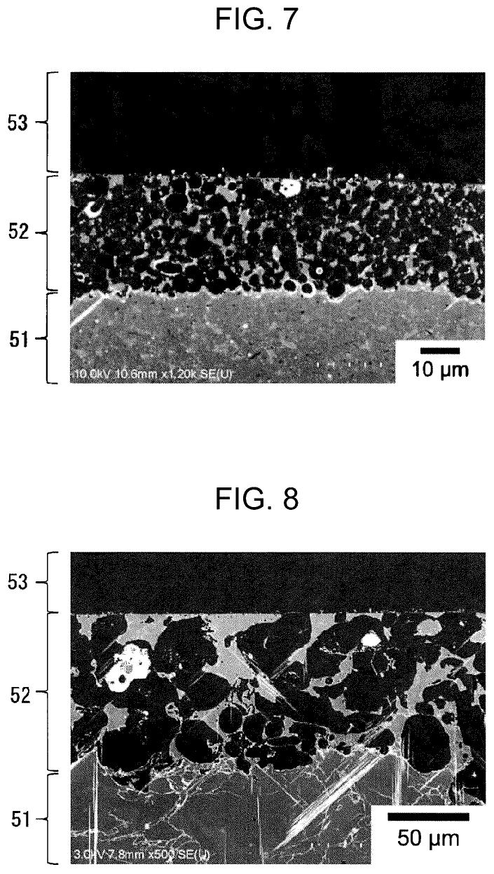

A side surface of a thermoelectric conversion element of Example 1 was polished with abrasive paper. Next, ion milling treatment was performed with an argon ion milling apparatus manufactured by Leica, Model EM TIC 3X, to expose a cross section of the thermoelectric conversion element and obtain a sample for cross-sectional observation. This sample was observed with a scanning electron microscope (SEM) manufactured by Hitachi High-Technologies Corporation, Model SU8220. FIG. 7 is a SEM image of a cross section of a joint portion of the thermoelectric conversion element according to Example 1. In FIG. 7, the layer indicated by the numeral “51” is the layer containing the thermoelectric conversion material. The layer indicated by the numeral “52” is the joining layer derived from the joining material. The layer indicated by the numeral “53” is the stainless steel plate. As shown in FIG. 7, a layer structure is observed in the joint portion of the thermoelectric conversion element according to Example 1. As shown in FIG. 7, in the joining layer indicated by the numeral “52,” a first part, which was a granular and dark part, and a second part, which was a bright part present among the particles, were observed. The thickness of this layer was about 30 μm. In the same field of view as that of FIG. 7, composition analysis was performed by energy dispersive X-ray spectroscopy (EDX). Consequently, in the second part of the joining layer, Sb and Bi contained in the thermoelectric conversion material were detected in addition to Mg. In the layer containing the thermoelectric conversion material, Cr, which was thought to be derived from the stainless steel, was detected in addition to Mg, Sb, and Bi. In the first part of the joining layer, Fe, Ni, and Cr were detected.

### Quantitative Analysis

Based on the SEM-EDX results described above, the content of each element in terms of number of atoms in the joining layer was determined. Table 1 lists the results. The size of the measurement field of view of SEM-EDX was adjusted such that the measurement results were average results in the joining layer by taking into consideration the influence of a measurement site on the measurement results.

### Examples 2 to 4 and Comparative Examples 1 to 3

Thermoelectric conversion elements according to Examples 2 to 4 and Comparative Examples 1 to 3 were produced in the same manner as in Example 1 except that the mass ratio of the amount of the stainless steel powder added to the amount of the Mg powder added was changed as listed in Table 1. In Comparative Example 1, the Mg powder was not added. For each of these thermoelectric conversion elements, the measurement of the electric resistance, cross-sectional observation, and quantitative analysis were performed in the same manner as in Example 1. Table 1 lists the results.

### Example 5

A thermoelectric conversion element according to Example 5 was produced in the same manner as in Example 1 except the following points. An oxygen-free copper plate was used instead of the stainless steel plate. In addition, the heating temperature of the sintering mold was adjusted to 680° C. For the thermoelectric conversion element according to Example 5, the measurement of the electric resistance, cross-sectional observation, and quantitative analysis were performed in the same manner as in Example 1. Table 1 lists the results.

### Example 6

A thermoelectric conversion element according to Example 6 was produced in the same manner as in Example 1 except the following point. Instead of the stainless steel powder used for the preparation of the joining material of Example 1, another stainless steel powder having a particle size less than or equal to 100 μm was used. The average particle size of this stainless steel powder was in a range of 60 to 80 μm. For the thermoelectric conversion element according to Example 6, the measurement of the electric resistance, cross-sectional observation, and quantitative analysis were performed in the same manner as in Example 1. Table 1 lists the results. FIG. 8 is a SEM image of a cross section of a joint portion of the thermoelectric conversion element according to Example 6. The thickness of the joining layer, which is the layer indicated by the numeral “52” in FIG. 8, was in a range of about 100 μm to 150 μm.

### Example 7

A thermoelectric conversion element according to Example 7 having the structure as illustrated in FIG. 3 was produced in the same manner as in Example 1 except the following point. A paste joining material containing Mg and Cu was applied to an oxygen-free copper disc, and the joining material was dried to obtain two copper plates with the joining material. Members were placed in a sintering mold in the following order. Here, the two copper plates with the joining material were disposed such that the joining material of the copper plate with the joining material was in contact with the stainless steel plate.

A punch made of carbon having an outer diameter of 20 mm

A carbon sheet having a diameter of 20 mm

A first copper plate with a joining material

A first stainless steel plate with the joining material

The powder of the thermoelectric conversion material in an amount of 5.0 g

A second stainless steel plate with the joining material

A second copper plate with a joining material

A carbon sheet having a diameter of 20 mm

A punch made of carbon having an outer diameter of 20 mm

For the thermoelectric conversion element according to Example 7, the measurement of the electric resistance, cross-sectional observation, and quantitative analysis were performed in the same manner as in Example 1. Table 1 lists the results.

As listed in Table 1, according to a comparison between the examples and the comparative examples, it was suggested that when a condition of 2.5≤α/β≤6.5 was satisfied in the joining layer of the thermoelectric conversion element, an increase in the electric resistance of the thermoelectric conversion element in high-temperature air was easily inhibited.

TABLE 1

| | Mass ratio | | | Content of each element | | | | | Electric | Electric | Ratio A/B of |
|---|---|---|---|---|---|---|---|---|---|---|---|
| | of stainless | | | in first joining layer | | | | | resistance A | resistance B | electric |
| | steel | First | Second | [atom %] | | | | | before heat | after heat | resistance A |
| | powder to | metal | metal | Mg | Sb + Bi | Fe + Ni | | | treatment | treatment | to electric |
| | Mg powder | layer | layer | (α) | (β) | (γ) | α/β | α/γ | [mΩ] | [mΩ] | resistance B |
| Example 1 | 99.0 | Stainless | Absent | 24.4 | 5.3 | 70.3 | 4.61 | 0.347 | 6 | 6.2 | 1.03 |
| | | steel | | | | | | | | | |
| Example 2 | 199.0 | Stainless | Absent | 19.7 | 5.9 | 74.4 | 3.31 | 0.265 | 7.7 | 9.6 | 1.25 |
| | | steel | | | | | | | | | |
| Example 3 | 32.3 | Stainless | Absent | 27.8 | 5.2 | 67.0 | 5.31 | 0.415 | 6.3 | 7 | 1.11 |
| | | steel | | | | | | | | | |
| Example 4 | 19.0 | Stainless | Absent | 29.1 | 5.0 | 65.9 | 5.81 | 0.441 | 6.9 | 8.7 | 1.26 |
| | | steel | | | | | | | | | |
| Example 5 | 99.0 | Oxygen-free | Absent | 23.3 | 5.5 | 71.3 | 4.27 | 0.327 | 12.5 | 14.1 | 1.13 |
| | | copper | | | | | | | | | |
| Example 6 | 99.0 | Stainless | Absent | 23.0 | 5.1 | 71.9 | 4.52 | 0.321 | 5.8 | 5.9 | 1.02 |
| | | steel | | | | | | | | | |
| Example 7 | 99.0 | Stainless | Oxygen-free | 23.7 | 5.4 | 70.9 | 4.40 | 0.335 | 5.2 | 6.4 | 1.23 |
| | | steel | copper | | | | | | | | |
| Comparative | 100/0 | Stainless | Absent | 17.4 | 11.5 | 71.0 | 1.51 | 0.246 | 6.5 | 127 | 19.5 |
| Example 1 | | steel | | | | | | | | | |
| Comparative | 499.0 | Stainless | Absent | 20.8 | 8.6 | 70.6 | 2.43 | 0.295 | 8.3 | 32.1 | 3.87 |
| Example 2 | | steel | | | | | | | | | |
| Comparative | 11.5 | Stainless | Absent | 28.8 | 4.3 | 66.9 | 6.73 | 0.431 | 9.3 | 25.3 | 2.72 |
| Example 3 | | steel | | | | | | | | | |

The thermoelectric conversion element of the present disclosure can be used for applications such as electric power generation and temperature control.

What is claimed is:

1. A thermoelectric conversion element comprising:
a first metal layer; and
a thermoelectric convertor containing Mg and at least one selected from the group consisting of Sb and Bi,
wherein
the thermoelectric convertor comprises:
a thermoelectric conversion layer; and
a first joining layer disposed between the first metal layer and the thermoelectric conversion layer in a thickness direction of the thermoelectric conversion layer,
the first joining layer contains at least one selected from the group consisting of Fe and Ni,
the first joining layer satisfies a first condition represented by 2.5≤α/β≤6.5, where
α is a content of Mg in terms of number of atoms in the first joining layer, and
β is a sum of contents of Sb and Bi in terms of number of atoms in the first joining layer, and
the first joining layer has a thickness of more than or equal to 0.01 mm and less than or equal to 0.2 mm.

2. The thermoelectric conversion element according to claim 1, wherein
the first joining layer includes particles containing at least one selected from the group consisting of Fe and Ni.

3. The thermoelectric conversion element according to claim 1, wherein
the first joining layer satisfies a second condition represented by 0.002<α/β<0.6, where γ is a sum of contents of Fe and Ni in terms of number of atoms in the first joining layer in the second condition.

4. The thermoelectric conversion element according to claim 1, wherein
a sum γ of contents of Fe and Ni in terms of number of atoms in the first joining layer satisfies a third condition of γ≥65%.

5. The thermoelectric conversion element according to claim 1, wherein
the first metal layer contains at least one selected from the group consisting of Fe, Ni, Cu, and Ag.

6. The thermoelectric conversion element according to claim 1, further comprising:
a second metal layer containing at least one selected from the group consisting of Cu and Ag,
wherein
the first metal layer is disposed between the second metal layer and the thermoelectric convertor in a thickness direction of the first metal layer and contains at least one selected from the group consisting of Fe and Ni.

7. A joining material comprising Mg and at least one selected from the group consisting of Fe and Ni, wherein
the joining material is capable of joining together a thermoelectric conversion material and a metal member.

8. A thermoelectric conversion module comprising:
a p-type thermoelectric conversion body;
an n-type thermoelectric conversion body; and
an electrode electrically connecting one end of the p-type thermoelectric conversion body and one end of the n-type thermoelectric conversion body to each other,
wherein
the n-type thermoelectric conversion body includes the thermoelectric conversion element according to claim 1.

9. A thermoelectric conversion system comprising:
the thermoelectric conversion module according to claim 8; and
a heat source disposed on a side closer to the electrode.

10. A method for generating electric power, comprising:
causing a temperature difference in the thermoelectric conversion module according to claim 8 using heat from a heat source to generate electric power.

11. A method for producing a thermoelectric conversion element, the method comprising:
heating a metal plate, a powder, and a joining material in a state in which the joining material is disposed between the metal plate and the powder in a thickness direction of the metal plate to sinter the powder and to join together the metal plate and a sintered body of the powder,
wherein
the joining material contains Mg and at least one selected from the group consisting of Fe and Ni, and
the powder contains Mg and at least one selected from the group consisting of Sb and Bi.

12. The method of production according to claim 11, wherein
the joining material contains particles containing at least one selected from the group consisting of Fe and Ni, and
an average particle size p of the particles satisfies a fourth condition represented by 0.5 μm≤p≤100 μm.

13. The method of production according to claim 1, wherein
the first joining layer includes a phase forming a solid phase different from the particles, the phase being present among the particles,
wherein
the phase contains Mg.

14. The method of production according to claim 1, wherein
In the first condition, a satisfies a condition where a is more than or equal to 19% and less than or equal to 30%.
